(19) United States
(12) Patent Application Publication
(10) Pub. No.: US 2025/0338487 A1
(43) Pub. Date: Oct. 30, 2025

(54) MANAGING WORD LINES IN SEMICONDUCTOR DEVICES

(71) Applicant: Yangtze Memory Technologies Co., Ltd., Wuhan (CN)

(72) Inventors: Zichen LIU, Wuhan (CN); Wei LIU, Wuhan (CN)

(21) Appl. No.: 18/777,925

(22) Filed: Jul. 19, 2024

(30) Foreign Application Priority Data
Apr. 29, 2024 (CN) 202410533583.8

(51) Int. Cl. H10B 12/00

(52) U.S. Cl. CPC H10B 12/488; H10B 12/0335

(57) ABSTRACT

Systems, devices, and methods for managing word lines in semiconductor devices are provided. In one aspect, a semiconductor device includes multiple blocks. Each block includes multiple rows of memory cells. Each row of memory cells extends along a first direction. A memory cell includes a transistor having a gate extending along a second direction perpendicular to the first direction. The semiconductor device also includes multiple word lines. A word line is coupled to gates of transistors of two adjacent rows of memory cells of two adjacent blocks that are spaced by a corresponding isolating region. The word line extends along the first direction. The semiconductor device further includes multiple conductive structures, and multiple insulating regions configured to separate adjacent word lines. The word line is connected to a corresponding conductive. An area of the corresponding conductive structure is within an area of the corresponding isolating region between two adjacent blocks.

### CROSS-REFERENCE TO RELATED APPLICATIONS

This application claims priority to Chinese Patent Application No. 202410533583.8, filed on Apr. 29, 2024, which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory DRAMs. The semiconductor memory devices can have various structures to increase a density of memory cells and lines on a chip. A memory device normally includes a memory array of memory cells and control circuitries for facilitating operations of the memory array.

### SUMMARY

The present disclosure describes methods, devices, systems and techniques for three-dimensional (3D) semiconductor devices.

One aspect of the present disclosure features a semiconductor device, including multiple blocks. Each block includes multiple rows of memory cells. Each row of memory cells extends along a first direction. A memory cell includes a transistor having a gate extending along a second direction perpendicular to the first direction. The semiconductor device also includes multiple word lines. A word line is coupled to gates of transistors of two adjacent rows of memory cells of two adjacent blocks that are spaced by a corresponding isolating region. The word line extends along the first direction. The semiconductor device further includes multiple conductive structures, and multiple insulating regions configured to separate adjacent word lines. The word line is connected to a corresponding conductive structure. An area of the corresponding conductive structure is within an area of the corresponding isolating region between two adjacent blocks.

In some implementations, the area of the corresponding conductive structure overlaps a portion of the word line.

In some implementations, the word line is a first word line. The two adjacent rows of memory cells of the two adjacent blocks are a first row of memory cells of a first block and a first row of memory cells of a second block. A second word line of the plurality of word lines is coupled to a second row of memory cells of the second block and a second row of memory cells of a third block adjacent to the second block. The first word line and the second word line are adjacent to each other at least along a third direction perpendicular to the first direction and the second direction.

In some implementations, the corresponding conductive structure is a first conductive structure. The plurality of conductive structures includes a second conductive structure coupled to the second word line. An area of the second conductive structure is within an area of a second corresponding isolating region between the second block and the third block.

In some implementations, the semiconductor device further includes a plurality of separation regions. A separation region of the plurality of separation regions is between adjacent rows of memory cells in a same block of the plurality of blocks. An insulating region of the plurality of insulating regions is on an end of the separation region. A second corresponding conductive structure of the plurality of conductive structures is within the insulating region and coupled to the separation region.

In some implementations, the insulating region is at an end of at least one adjacent word line of the plurality of word lines. The at least one adjacent word line is adjacent to the separation region along a third direction perpendicular to the first direction and the second direction.

In some implementations, two adjacent conductive structures of the plurality of conductive structures are coupled to two adjacent separation regions of the plurality of separation regions of two adjacent blocks of the plurality of blocks. The two adjacent separation regions are adjacent to each other along the first direction. The adjacent conductive structures are on two ends of a corresponding isolating region between the two adjacent separation regions of the two adjacent blocks. The two ends of the corresponding isolating region are opposite to each other along the first direction.

In some implementations, two conductive structures of the plurality of conductive structures coupled to two adjacent separation regions of a same block are on opposite ends of the two adjacent separation regions. The two adjacent separation regions of the same block are adjacent to each other along the third direction. The opposite ends are opposite to each other along the first direction.

Another aspect of the present disclosure features a semiconductor device including a plurality of blocks, a plurality of conductive structures, and a plurality of insulating regions. Two adjacent blocks of the plurality of blocks are separated by a corresponding isolating region. A block of the plurality of blocks includes a plurality of rows of memory cells. Each row of memory cells extends along a first direction. A memory cell of the plurality of rows of memory cells includes a transistor having a gate extending along a second direction perpendicular to the first direction. The block also includes a plurality of word lines extending along the first direction. A word line of the plurality of word lines is coupled to gates of transistors of a corresponding row of memory cells of the block of the plurality of blocks. The insulating regions are configured to separate adjacent word lines of the plurality of word lines. The plurality of blocks includes a first block and a second block. A first row of memory cells and a second row of memory cells of the first block are sequential along a third direction perpendicular to the first direction and the second direction. A first row of memory cells of the second block is adjacent to the first row of memory cells of the first block along the first direction. A first word line of the plurality of word lines is coupled to the second row of memory cells of the first block. A second word line of the plurality of word lines is coupled to the first row of memory cells of the second block. The first word line and the second word line are connected through a corresponding conductive structure of the plurality of conductive structures. An area of the corresponding conductive structure is within an area of a corresponding isolating region between the first block and the second block.

In some implementations, the connected first word line and second word line has a zig-zag shape.

In some implementations, the corresponding conductive structure is separate from the plurality of insulating regions.

In some implementations, the first word line and the second word line are connected to form a first continuous conductive line. A third word line of the plurality of word lines is coupled to a second row of memory cells of the second block. A fourth word line is coupled to a first row of memory cells of a third block adjacent to the second block along the first direction. The corresponding conductive structure is a first conductive structure, and the plurality of conductive structures includes a second conductive structure. The third word line and the fourth word line are connected through the second conductive structure of the plurality of conductive structures to form a second continuous conductive line. The first continuous conductive line and the second continuous conductive line are adjacent to each other along the first direction and a third direction perpendicular to the first direction and the second direction.

In some implementations, the semiconductor device further includes a plurality of separation regions. A separation region of the plurality of separation regions is configured to separate adjacent rows of memory cells in a same block of the plurality of blocks. An insulating region of the plurality of insulating regions is on an end of the separation region. A second corresponding conductive structure of the plurality of conductive structures is within the insulating region and coupled to the separation region.

In some implementations, the insulating region is at an end of at least one adjacent word line of the plurality of word lines. The at least one adjacent word line is adjacent to the separation region along a third direction perpendicular to the first direction and the second direction.

In some implementations, the separation region is a first separation region of the first block. The corresponding conductive structure is a first conductive structure. The first separation region has a first end and a second end opposite to the first end along the first direction. A corresponding second separation region of the second block has a third end and a fourth end opposite to the third end along the first direction. The corresponding second separation region is adjacent to the first separation region along the first direction. The second end of the first separation region and the third end of the corresponding second separation region are at two ends of the corresponding isolating region between the first block and the second block. The first conductive structure is on the first end of the first separation region. A second conductive structure of the plurality of conductive structures coupled to the corresponding second separation region is on the third end of the corresponding second separation region.

In some implementations, two conductive structures of the plurality of conductive structures coupled to two adjacent separation regions of the plurality of separation regions of a same block are on opposite ends of the two adjacent separation regions. The two adjacent separation regions of a same block are adjacent to each other along the third direction. The opposite ends are opposite to each other along the first direction.

Another aspect of the present disclosure features a method including: a plurality of blocks is formed. Two adjacent blocks of the plurality of blocks are separated by a corresponding isolating region. A block of the plurality of blocks includes a plurality of rows of memory cells, and a plurality of word lines. Each row of memory cells extends along a first direction. A memory cell of the plurality of rows of memory cells includes a transistor having a gate extending along a second direction perpendicular to the first direction. The plurality of word lines extends along the first direction. A word line of the plurality of word lines is coupled to gates of transistors of a corresponding row of memory cells of a block of the plurality of blocks. A plurality of conductive structures is formed. A plurality of insulating regions are formed and configured to separate adjacent word lines of the plurality of word lines. A first word line of the plurality of word lines in a first block of the plurality of blocks and a second word line of the plurality of word lines in a second block of the plurality of blocks are connected to a corresponding conductive structure of the plurality of conductive structures. The first block is adjacent to the second block along the first direction. An area of the corresponding conductive structure is within an area of a corresponding isolating region between the first block and the second block.

In some implementations, the first word line is coupled to a first row of memory cells of the first block. The second word line is coupled to a first row of memory cells of the second block. The first row of memory cells of the first block and the first row of memory cells of the second block are spaced from each other along the first direction.

In some implementations, the first block includes a first row of memory cells and a second row of memory cells that are sequential along a third direction perpendicular to the first direction and the second direction. The second block includes a first row of memory cells and a second row of memory cells that are sequential along the third direction. The first word line is coupled to the second row of memory cells of the first block. The second word line is coupled to the first row of memory cells of the second block. The second row of memory cells of the first block and the first row of memory cells of the second block are spaced from each other along the first direction and the third direction.

In some implementations, a plurality of separation regions is formed which extends along the first direction. A separation region of the plurality of separation region is configured to separate adjacent rows of memory cells in a same block of the plurality of blocks. An insulating region of the plurality of insulating regions is formed on an end of the separation region. A second corresponding conductive structure of the plurality of conductive structures is formed within the insulating region and coupled to the separation region.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example 3D semiconductor device.

FIGS. 2A-2B illustrates diagrams of example peripheral circuitry blocks in a semiconductor structure.

FIG. 3A illustrates a top view of an example semiconductor device.

FIG. 3B illustrates a top view of another example semiconductor device.

FIGS. 4A-4C illustrates views of an example semiconductor device at various stages of manufacturing process.

FIG. 5 illustrates a flow chart of an example process to form a semiconductor device.

FIG. 6 illustrates a block diagram of an example system.

It is to be understood that the various exemplary implementations shown in the figures are merely illustrative representations and are not necessarily drawn to scale.

### DETAILED DESCRIPTION

In a memory device, word lines are connected to gates of corresponding transistors. Word lines in adjacent memory blocks can be coupled together to a word line driver through conductive contracts or vias. In some cases, the coupling between different word lines can be established through a conductive contact dedicated to each word line. These conductive contacts are interconnected through an additional layer of metal in a different plane. The additional layer of metal is then coupled to word line drivers. The word line drivers apply electrical signals or pulses to the word lines, controlling the operations of memory cells in neighboring blocks. Word line drivers can be positioned around the peripheral of memory arrays. Word line drivers can be also formed on a separate semiconductor substrate, e.g., a control structure, from the memory array substrate to enhance storage capacity.

Implementations of the present disclosure provides a semiconductor device and a method to form a semiconductor device. In one aspect, the semiconductor device includes multiple blocks. Each block includes multiple rows of memory cells. Each row of memory cells extends along a first direction. A memory cell includes a transistor having a gate extending along a second direction perpendicular to the first direction. The semiconductor device also includes multiple word lines. A word line is coupled to gates of transistors of two adjacent rows of memory cells of two adjacent blocks that are spaced by a corresponding isolating region. The word line extends along the first direction. The semiconductor device further includes multiple conductive structures, and multiple insulating regions configured to separate adjacent word lines. The word line is connected to a corresponding conductive, and an area of the corresponding conductive structure is within an area of the corresponding isolating region between the two adjacent rows of memory cells of the two adjacent blocks.

Implementations of the present disclosure can provide one or more of the following technical advantages and/or benefits. First, adjacent word lines in adjacent memory blocks can be coupled together via a single conductive contact, rather than each requiring its own conductive contact, which can reduce a lateral space needed for forming conductive contacts, thus increasing a storage capacity. In addition, these techniques are compatible with trench isolation (TISO) with shielding conductive material (e.g., metal). The shielding conductive material in the TISO can be connected to a low voltage (e.g., ground or a fixed negative voltage) to reduce charge build-up in the memory cells, thereby mitigating the floating body effect in the memory cells. Further, the techniques described herein enable a broader process window for forming conductive contacts for TISO. An insulating region made of a dielectric material can be first formed at an end of TISO, followed by conductive contacts formation. The insulating regions can be utilized to cut the ends of sequential word lines within the same block. The lateral dimension of the insulating region can be greater than the spaces between two sequential word lines. Absent such insulating regions, the process window for conductive contacts may be restricted by the space between two sequential word lines in the same memory block. With the techniques described in the present disclosure, the process window for conductive contacts can be determined by the lateral dimension of the insulating region, which is greater than that of the spacing between sequential word lines. Consequently, the techniques can expand or enlarge the process window for forming conductive contacts.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

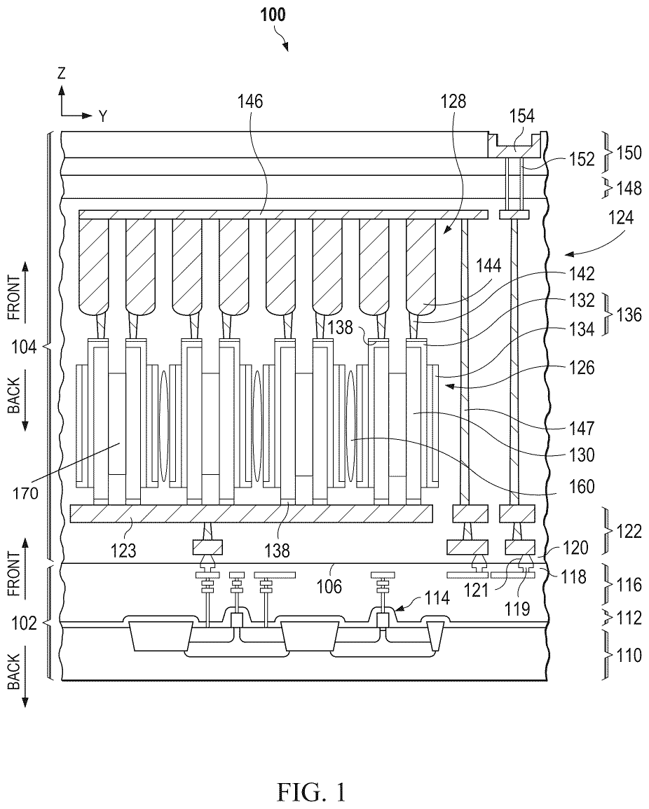

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 (the active region in which a channel can form) extending vertically (in the z-direction), and a gate structure 136 in contact with one side of semiconductor body 130. In a single-gate vertical transistor, the semiconductor body 130 can have a cuboid shape or a cylinder shape, and the gate structure 136 can abut a single side of semiconductor body 130 in a plane view, e.g., as shown in FIG. 1. In some implementations, the vertical transistor 126 has a structure including two or more gates, e.g., a two-gates structure, a three-gates structure, or a gate all around (GAA) structure. In some implementations, the gate structure 136 includes a gate electrode 134 and a gate dielectric 132 laterally between the gate electrode 134 and the semiconductor body 130 in a bit line direction (e.g., in the Y direction). In some implementations, the gate dielectric 132 abuts one side of the semiconductor body 130, and the gate electrode 134 abuts the gate dielectric 132.

As shown in FIG. 1, in some implementations, the semiconductor body 130 has two ends (the upper end and lower end in FIG. 1) in the vertical direction (the z-direction), and at least one end (e.g., the lower end) extends beyond gate dielectric 132 in the vertical direction (the z-direction) into the ILD layers. In some implementations, one end (e.g., the upper end) of the semiconductor body 130 is flush with the respective end (e.g., the upper end) of the gate dielectric 132. In some implementations, both ends (the upper end and lower end) of the semiconductor body 130 extend beyond the gate electrode 134, respectively, in the vertical direction (the z-direction) into ILD layers. That is, the semiconductor body 130 can have a larger vertical dimension (e.g., the depth) than that of the gate electrode 134 (e.g., in the z-direction), and neither the upper end nor the lower end of semiconductor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a source and a drain (both referred to as 138 as their locations may be interchangeable) disposed at the two ends (the upper end and lower end) of the semiconductor body 130, respectively, in the vertical direction (the z-direction). In some implementations, one of the source and drain 138 (e.g., at the upper end in FIG. 1) is coupled to the capacitor 128, and the other one of source and drain 138 (e.g., at the lower end in FIG. 1) is coupled to the bit line 123. That is, the vertical transistor 126 can have a first terminal in the positive z-direction and a second terminal opposite the first terminal in the negative z-direction, as shown in FIG. 1.

In some implementations, the semiconductor body 130 includes semiconductor materials, such as single crystalline silicon, polysilicon, amorphous silicon, Ge, any other semiconductor materials, or any combinations thereof. In one example, semiconductor body 130 may include single crystalline silicon. Source and drain 138 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between source/drain 138 of the vertical transistor 126 and the bit line 123 as the bit line contact or between source/drain 138 of the vertical transistor 126 and the first electrode of the capacitor 128 as capacitor contact 142 to reduce the contact resistance. In some implementations, gate dielectric 132 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the X direction) as a word line, the second semiconductor structure 104 of the 3D semiconductor device 100 can also include a plurality of word lines each extending in the word line direction. Each word line 134 can be coupled to a row of DRAM cells 124. That is, the bit line 123 and the word line 134 can extend in two perpendicular lateral directions, and the semiconductor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1.

In some implementations, as shown in FIG. 1, the vertical transistor 126 extends vertically through and contacts the word lines 134, and the source or drain 138 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the Y direction). As shown in FIG. 1, two adjacent vertical transistors 126 in the bit line direction are mirror-symmetric to one another with respect to a trench isolation 160. That is, the second semiconductor structure 104 can include a plurality of trench isolations 160 each extending in the word line direction (the X direction) in parallel with word lines 134 and disposed between vertical gates 134 of two adjacent rows of the vertical transistors 126. In some implementations, the rows of vertical transistors 126 separated by the trench isolation 160 are mirror-symmetric to one another with respect to the trench isolation 160. The trench isolation 160 can be formed with dielectric materials including, but not limited to, silicon oxide, silicon nitride, silicon oxynitride, low-k dielectrics, or any combination thereof. It is understood that the trench isolation 160 may include an air gap each disposed laterally between adjacent vertical gates 134. Air gaps may be formed due to the relatively small pitches of vertical transistors 126 in the bit line direction (e.g., the Y direction). On the other hand, the relatively small dielectric constant of air in air gaps (e.g., about 1) compared to silicon dioxide (e.g., about 3.9) can reduce capacitance between adjacent conductors, thereby reducing crosstalk and improving overall device performance. Similarly, in some implementations, air gaps are formed laterally between word lines/gate electrodes 134 in the bit line direction as well, depending on the pitches of word lines/gate electrodes 134 in the bit line direction.

In some implementations, instead of the trench isolation 160 having the air gap being disposed between adjacent vertical gates 134 of two adjacent rows of the vertical transistors 126, a shielding conductive structure 170 (e.g., including metal such as W) is disposed between adjacent semiconductor bodies 130 of two adjacent rows of vertical transistors 126. The shielding conductive structure 170 can be in contact with at least one of the adjacent semiconductor bodies 130 and can be coupled to a low voltage (e.g., a fixed negative voltage), which can reduce charge build-up in the memory cells 124, thereby mitigating the floating body effect in the memory cells 124. Moreover, by applying a fixed low voltage on the shielding conductive structure 170 between the memory cells 124, a threshold voltage of the memory cells 124 can be conveniently adjusted, which can reduce the overall manufacturing complexity and cost, and improve reliability of the memory cells 124. Further, the shielding conductive structure 170 can be coupled out from a same side as word lines or a different side from the word lines. For example, the shielding conductive structure 170 can be coupled out from the back side of the second semiconductor structure 104. The shielding conductive structure 170 can be also referred as shielding conductive material. The trench isolation having such shielding conductive structure 170 can be referred as trench isolation (TISO) or the separation region in this disclosure.

As shown in FIG. 1, in some implementations, a capacitor 128 includes a first electrode 144 above and coupled to the source or drain 138 of vertical transistor 126, e.g., the upper end of the semiconductor body 130, via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to source or drain 138 of a respective vertical transistor 126 in the same DRAM cell, while all second electrodes are coupled to a common plate 146 coupled to the ground, e.g., a common ground. The capacitor 128 can have a first end in the negative z-direction and a second end opposite the first end in the positive z-direction, as shown in FIG. 1. In some implementations, the first end of the capacitor 128 is coupled to the first terminal of the vertical transistor 126 via an ohmic contact (e.g., the capacitor contact 142 made of a metal silicide material). As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1. In some implementation, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, vertical transistor 126 extends vertically through and contacts the word lines 134, source or drain 138 of vertical transistor 126 at the lower end thereof is in contact with the bit line 123, and source or drain 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, the second semiconductor structure 104 further includes a substrate 148 disposed above the DRAM cells 124. The substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron- or tens micron-level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines 134 and/or between semiconductor bodies 130 may be partially or fully filled with dielectrics. Although not shown, it is further understood that more than one array of DRAM cells 124 may be stacked over one another to vertically scale up the number of DRAM cells 124.

In some implementations, instead of having the substrate 148 above the DRAM cells 124 as shown in FIG. 1, the second semiconductor structure 104 includes a substrate disposed below the DRAM cells 124. The substrate can be part of a carrier wafer. The DRAM cells 124 can be formed in a front side of the substrate, and the bit lines 123 can be formed in a back side of the substrate. The bit lines 123 can be conductively coupled to the DRAM cells 124 (e.g., the terminals 138 of the vertical transistors 126) through the substrate.

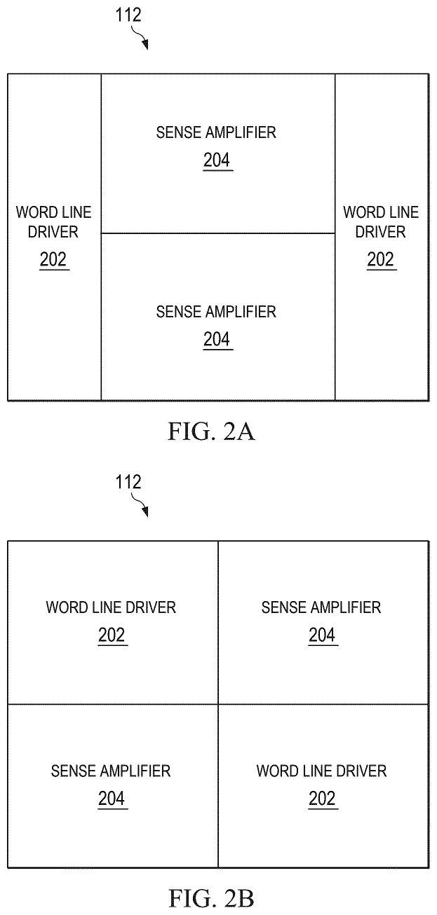

FIGS. 2A-2B illustrate schematic diagrams of example peripheral circuitries in the first semiconductor structure 102. To access or manipulate data stored in memory cells such as the DRAM cells 124, a peripheral circuitry 112, including various components and control mechanisms, is employed. This peripheral circuitry 112 can serve as the interface between the memory cells and the external system, facilitating read, write, and/or erase operations. Through a series of signals and commands, the peripheral circuitry 112 can coordinate the operations of data in the memory cells, and enable communication between a memory cell array and a broader system architecture.

The peripheral circuitry 112 can include one or more word line drivers 202. A word line driver 202 can be connected to the memory cell array via word lines and select/drive one or more word lines to perform an operation on memory cell coupled to a selected word line. In some cases, when a particular row (word line) needs to be accessed for a read or write operation, the word line driver 202 can activate a word line by sending appropriate signals. Once the word line is activated, the memory cells connected to the word line become accessible for read or write operations. The specific operation performed on the memory cells can include reading data stored in the memory cells or writing new data into the memory cells.

The peripheral circuitry 112 can further include a sense amplifier 204 that can be configured to read and program (write) data from and to the memory cell array according to control signals from a memory controller. In one example, the sense amplifier 204 can store one codeword of program data (write data) to be programmed into the memory cell array. In another example, the sense amplifier 204 can perform program verify operations to ensure that the data has been properly programmed into selected memory cells coupled to selected word lines. In yet another example, the sense amplifier 204 can also sense low power signals from a bit line 123 that represents a data bit stored in a memory cell and amplify the small voltage swing to recognizable logic levels in a read operation. It is understood that other suitable circuitries can also be included in the peripheral circuitry 112.

To achieve a higher memory cell capacity, the peripheral circuitry 112 can be formed on a separate semiconductor substrate different from an array die or wafer (e.g., the second semiconductor structure 104). For example, the peripheral circuitry 112 can be formed on the first semiconductor structure 102 as described in FIG. 1. As illustrated in FIG. 2A, the word line driver 202 of the peripheral circuitry 112 can be arranged at peripherals of the sense amplifier 204, e.g., on two sides of the sense amplifier 204. The lateral size of the memory array die can be similar to that of the sense amplifier 204. Word lines can be connected to the word line driver 202 through interconnection conductive structures disposed on peripherals surrounding the memory cell array in the second semiconductor structure 104.

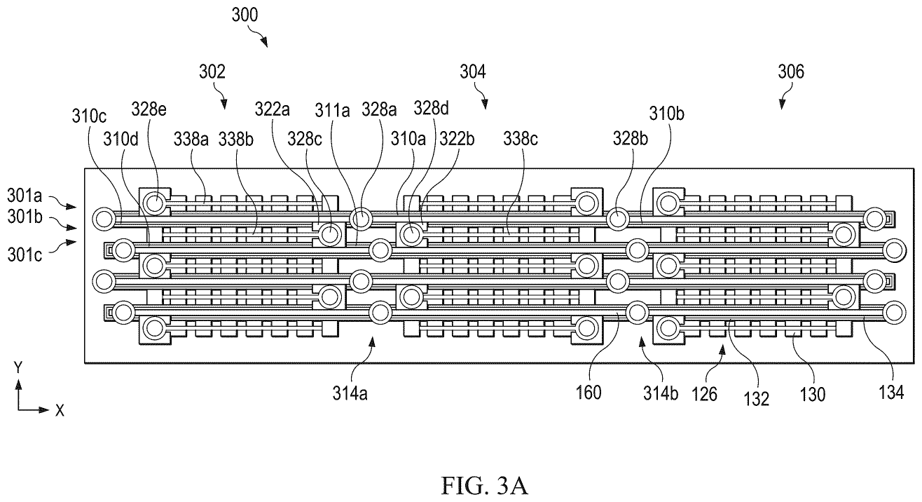

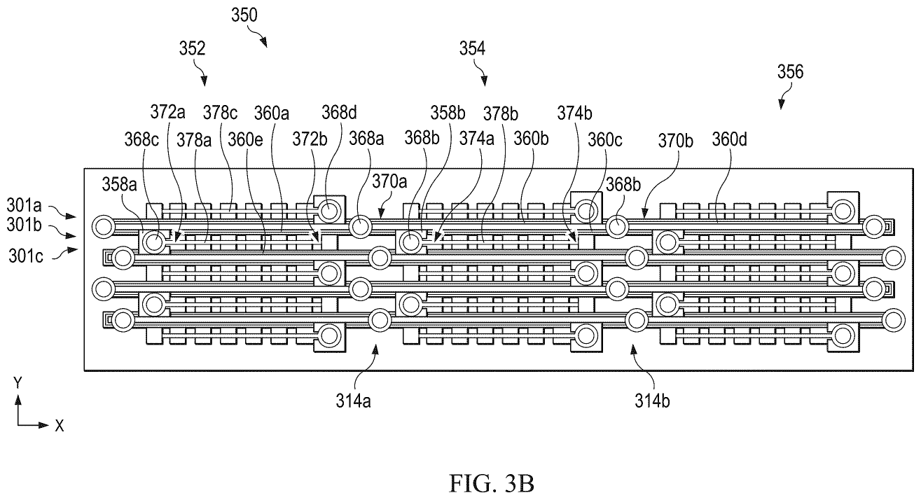

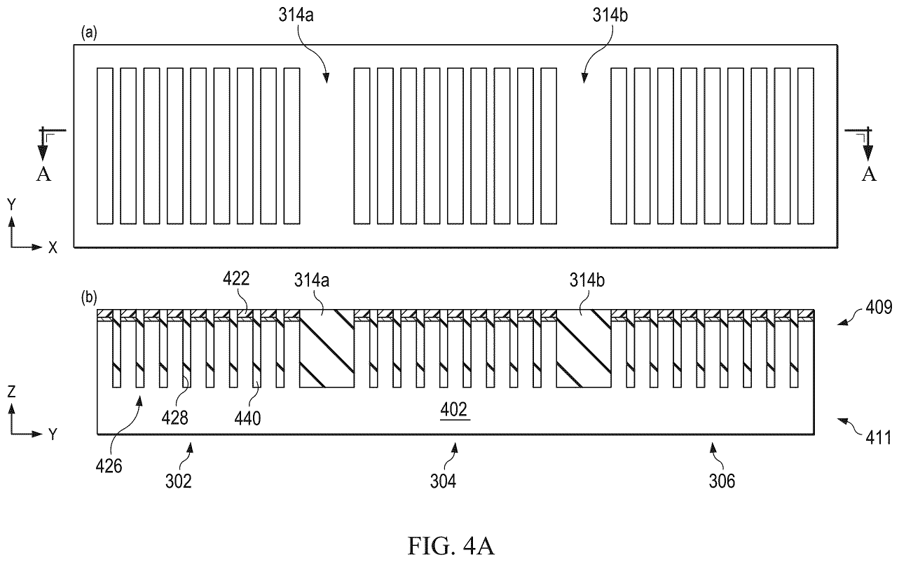

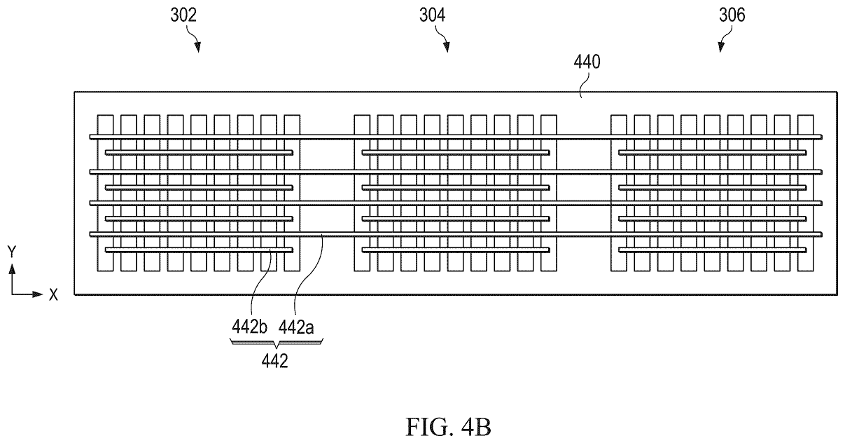

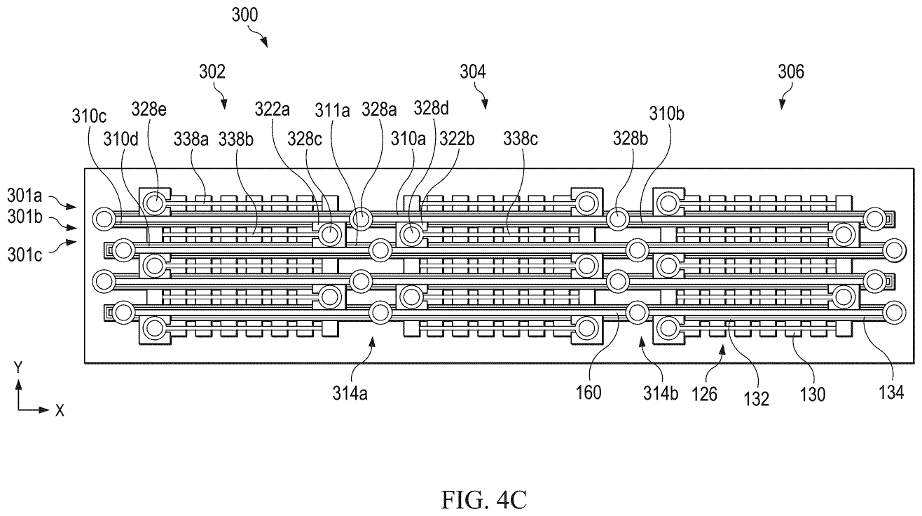

In some implementations, as illustrated in FIG. 2B, the techniques described in the present disclosure enhance memory cell capacity by simplifying interconnections routings between the word lines and the word line driver 202, such that the word line driver 202 can be positioned with the sense amplifier 204 and/or other circuitry in a smaller peripheral circuitry 112. In some implementations, the lateral size of the peripheral circuitry 112 closely matches that of a memory array die. Each memory array die can include one or more memory banks, with each bank having one or more memory arrays. As described with further details in FIGS. 3A-4C, the techniques involve coupling two adjacent word lines in neighboring memory blocks via a single conductive contact, thereby minimizing the lateral space required for conductive contact formation for each word line. The single conductive contact coupling two adjacent word lines in the second semiconductor structure 104 is connected to a corresponding word line driver 202 in the peripheral circuitry 112 of the first semiconductor structure 102. By locating the single conductive contact in the separation space between two neighboring memory arrays, no additional space needs to be allocated around a memory bank for interconnection line routings to connect the word lines with the word line driver 202. Therefore, this configuration contributes to further increasing the storage density in a memory device.

FIG. 3A illustrates a top view of an example semiconductor device 300. The semiconductor device 300 can be implemented as the second semiconductor structure 104 in FIG. 1. As shown, the semiconductor device 300 includes multiple blocks, e.g., a first block 302, a second block 304, and a third block 306. The first block 302, the second block 304, and the third block 306 can be sequential to each other along a first direction, e.g., X direction or word line direction. Adjacent blocks can be spaced by a corresponding isolating region, e.g., a first isolating region 314a between the first block 302 and the second block 304, a second isolating region 314b between the second block 304 and the third block 306. The isolating regions 314a, 314b can be formed with a dielectric material including, but not limited to, silicon oxide, silicon nitride, silicon oxynitride, or any combination thereof. The first isolating region 314a and/or the second isolating region 314b can be referred to generally as isolating regions 314 and individually as an isolating region 314. Each block can include multiple rows of memory cells. Each row of memory cells extends along the first direction, e.g., X direction, and can include one or more memory cells. A memory cell includes a transistor 126. As described in FIG. 1, the transistor 126 can include a semiconductor body 130 and a gate structure. The gate structure can include a gate dielectric layer 132 and a gate electrode or a gate 134. The gate 134 extends along a second direction, e.g., Z direction, as illustrated in FIG. 1. Z direction is perpendicular to the X direction. Adjacent transistors 126 can be separated by the trench isolation 160 or the separation regions 338 as described with further details below.

As shown in FIG. 3A, the semiconductor device 300 can further include multiple word lines, e.g., the first word line 310a, the second word line 310b. Different word lines in the semiconductor device 300 can be referred to generally as word lines 310 and individually as a word line 310. The word lines 310 extend along the first direction, e.g., X direction. In some implementations, a word line 310 is coupled to gates 134 of transistors of two adjacent rows of memory cells in two adjacent blocks. The gates 134 can be part of a corresponding word line 310. For example, as shown in FIG. 3A, the first word line 310a can connect the first row 301a of memory cells in the first block 302 and the first row 301a of memory cells in the second block 304. In another example, the second word line 310b can connect the second row 301b of memory cells in the second block 304 and the second row 301b of memory cells in the third block 306. In some implementations, the first row 301a of memory cells of the second block 304 and the second row 301b of memory cells of the second block 304 are sequential to each other along a third direction, e.g., Y direction or bit line direction.

In some implementations, the first word line 310a and the second word line 310b are adjacent to each other at least along the third direction. As shown, the first word line 310a and the second word line 310b can be at least partially located at different rows of a same memory block, e.g., the second block 304. Therefore, the first word line 310a and the second word line 310b can be adjacent to each other along Y direction in the second block 304.

Each word line 310 is connected to at least one conductive structure. For example, as illustrated in FIG. 3A, the first word line 310a is connected to a first conductive structure 328a, while the second word line 310b is connected to a second conductive structure 328b. Such conductive structures 328a, 328b can be referred to generally as conductive structures 328 or conductive contacts 328 and individually as a conductive structure 328 or conductive contact 328. The conductive structures 328 can electrically connect the word line 310 to peripheral circuitries 112 such that the peripheral circuitries 112 can control and manage the operations of memory cells. In some implementations, a word line 310 is utilized to synchronously control two adjacent rows of memory cells in neighboring blocks. For example, the first word line 310a can be utilized to control the first row 301a of memory cells in the first block 302 and the first row 301a of memory cells in the second block 304 synchronously.

The conductive structure 328 can be formed in the corresponding isolating region 314 between two adjacent blocks. In some implementations, an area of the corresponding conductive structure 328 is within an area of the corresponding isolating region 314 between the adjacent blocks. For example, as illustrated in FIG. 3A, the first conductive structure 328a is in the first isolating region 314a between the first block 302 and the second block 304. The first conductive structure 328a has a smaller area than that of the first isolating region 314a such that the first conductive structure 328a is away from the semiconductor bodies 130 in adjacent blocks. Likewise, an area of the second conductive structure 328b can be within an area of a second corresponding isolating region 314b between the second block 304 and the third block 306.

Multiple insulating regions 322 can be formed to separate adjacent word lines 310. For example, the first insulating region 322a and the second insulating region 322b can separate the third word line 310c from the second word line 310b. In some implementations, between two adjacent insulating regions 322, dummy conductive lines are formed in the isolating region between two adjacent memory blocks. For example, the dummy conductive line 311a can be formed between the first insulating region 322a and the second insulating region 322b. The insulating regions 322 can be formed with a dielectric material, including but not limited to, silicon oxide, silicon nitride, silicon oxynitride, or any combination thereof. The insulating regions 322 can also be referred as gate cut region in the present disclosure.

In some implementations, the insulating region 322 is at an end of at least one adjacent word lines, where the word lines are adjacent to the separation region along the third direction, e.g., Y direction. For example, as shown in FIG. 3A, the first insulating region 322a can cut or intersect the same ends, e.g., the right ends, of both the third word line 310c and the fourth word line 310d. The first insulating region 322a can be between the third word line 310c and the fourth word line 310d in the first block 302 along Y direction.

In some implementations, a conductive structure 328 is separate from the insulating regions 322. For example, the first conductive structure 328a is not in contact with any insulating region 232.

In some implementations, the conductive structure 328 extends along the second direction, e.g., the Z direction. Z direction is perpendicular to both the word line direction, e.g., X direction, and the bit line direction, e.g., the Y direction.

In some implementations, an area of a conductive structure 328 overlaps a portion of the word line 310. As illustrated in FIG. 3A, the first conductive structure 328a overlaps a portion of the first word line 310a such that the first conductive structure 328a is electrically connected to the first word line 310a. The first conductive structure 328a can be further coupled to a peripheral circuitry 112 including word line driver 202 for managing memory cell operations through the corresponding word line 310, e.g., the first word line 310a.

In some implementations, the semiconductor device 300 includes multiple separation regions 338. A separation region 338 is between adjacent rows of memory cells in a same block. The separation region 338 can be also referred as TISO 338 in the present disclosure. For example, the second separation region 338b can be located between the second row 301b of memory cells and the third row 301c of memory cells in the first block 302. The third row 301c of the memory cells are adjacent to or sequential to the second row 301b of memory cells along Y direction, e.g., bit line direction.

In some implementations, an insulating region 322 is formed on an end of the separation region 338 (TISO). A conductive structure 328 is within the insulating region 322 and electrically coupled to the corresponding separation region 338. For example, the first insulating region 322a can be formed on the end of the second separation region 338b (TISO). The third conductive structure 328c can be within the first insulating region 322a. A lateral dimension of the third conductive structure 328c can be smaller than that of the first insulating region 322a. The third conductive structure 328c can be electrically connected to the TISO 338. As described above, TISO 338 can include a shielding conductive structure 170 (e.g., including metal such as W). In some implementations, conductive structures 328 partially extend into the corresponding insulating regions 322 along Z direction such that the conductive structures 328 can be in contact with the shielding conductive structure 170 in a TISO 338. The TISO 338 can be coupled to a low voltage (e.g., a fixed negative voltage), which can reduce charge build-up in the memory cell and thus mitigate the floating body effect in the memory cells. Moreover, by applying a fixed low voltage on the TISO 338 between the memory cells, a threshold voltage of the memory cells can be conveniently adjusted, which can reduce the overall manufacturing complexity and cost, and improve reliability of the memory cells.

In some implementations, two adjacent conductive structures 328 are coupled to two adjacent separation regions 338 (TISOs) in two adjacent blocks. For example, the third conductive structure 328c and the fourth conductive structure 328d can be adjacent to each other. The third conductive structure 328c can be coupled to the second separation region 338b in the first block 302, while the fourth conductive structure 328d can be coupled to the third separation region in the second block 304. The second separation region 338b can be adjacent to the third separation region 338c along the word line direction.

In some implementations, the adjacent conductive structures 328 are on two ends of a corresponding isolating region 314 between the two adjacent separation regions 338 of the two adjacent blocks. The two ends of the corresponding isolating region 314 can be opposite to each other along the first direction, e.g., the word line direction. For example, as shown in FIG. 3A, the first isolating region 314a can be between the first block 302 and the second block 304. The third conductive structure 328c can be on the left end of the first isolating region 314a, while the fourth conductive structure 328d can be on the right end of the first isolating region 314a. The left end and the right end of the first isolating region 314a can be opposite to each other along the X direction, e.g., the word line direction.

In some implementations, two conductive structures 328 coupled to two adjacent separation regions 338 of a same block are on opposite ends of the two adjacent separation regions 338. The two adjacent separation regions 338 of the same block can be adjacent to each other along the third direction, e.g., Y direction or bit line direction. For example, as illustrated in FIG. 3A, in the first block 302, the first separation region 338a (TISO) is adjacent to the second separation region 338b (TISO). The fifth conductive structure 328e can be on an end, e.g., the left end. of the first separation region 338a. The third conductive structure 328c can be on an end, e.g., the right end, of the second separation region 338b. The left end is opposite to the right end along word line direction, e.g., X direction. In other words, conductive structures 328 can be located on opposite ends of the adjacent separation regions 338 in the same block.

FIG. 3B illustrates a top view of another example semiconductor device 350. The semiconductor device 350 can be implemented as the second semiconductor structure 104 in FIG. 1. As shown in FIG. 3B, the semiconductor device 350 includes multiple blocks, e.g., a first block 352, a second block 354, and a third block 356. The first block 352, the second block 354, and the third block 356 can be sequential to each other along the first direction, e.g., X direction or the word line direction. Adjacent blocks can be spaced by a corresponding isolating region 314. For example, the first isolating region 314a can be between the first block 352 and the second block 354. The isolating region 314 can be formed with a dielectric material including, but not limited to, silicon oxide, silicon nitride, silicon oxynitride, or any combination thereof.

Each block includes multiple rows of memory cells 301. Each row of memory cells extends along the first direction, e.g., X direction or the word line direction. In some implementations, the first row 301a of memory cells of the first block 352 and the second row 301b of memory cells of the first block 352 are sequential to each other along the third direction, e.g., Y direction or the bit line direction. Likewise, the first row 301a of memory cells of the second block 354 and the second row 301b of memory cells of the second block 354 can be sequential to each other along the bit line direction. In some implementations, a first row 301a of memory cells of the second block 354 is adjacent to the first row 301a of memory cells of the first block 352 along the first direction, e.g., X direction or the word line direction.

In some implementations, a memory cell includes a transistor 126. As described in FIG. 1, the transistor 126 can include a semiconductor body 130 and a gate structure. The gate structure can include a gate dielectric layer 132 and a gate electrode or a gate 134. The gate 134 can extend along a second direction, e.g., Z direction perpendicular to both the bit line direction and the word line direction, as illustrated in FIG. 1.

As shown in FIG. 3B, the semiconductor device 350 includes multiple word lines 360, e.g., the first word line 360a, the second word line 360b. Different word lines, e.g., 360a, 360b, in the semiconductor device 350 can be referred to generally as word lines 360 and individually as word line 360 in the present disclosure. The word lines 360 extend along the first direction, e.g., X direction. In some implementations, a word line 360 is coupled to gate 134 of transistors of a corresponding row of memory cells of the block. For example, the first word line 360a is coupled to gate of transistors of the second row 301b of the memory cells in the first block 352, while the second word line 360b is coupled to gate of transistors of the first row 301a of the memory cells in the second block 354. In some implementations, the gates 134 are part of a corresponding word line 360.

Each word line 360 is connected to at least one conductive structure 368. Two word lines in adjacent blocks can be connected through a corresponding conductive structure. For example, the first word line 360a and the second word line 360b can be connected through a corresponding conductive structure, e.g., the first conductive structure 368a. In some implementations, the area of the first conductive structure 368a overlaps a portion of the first word line 360a and a portion of the second word line 360b, as shown in FIG. 3B.

The first word line 360a and the second word line 360b can form a first continuous conductive line 370a. The first continuous word line 370a can couple to the word line driver 202 through the first conductive structure 368a. In some implementations, the connected first word line 360a and second word line 360b, e.g., the first continuous word line 370a, has a zig-zag shape, as illustrated in FIG. 3B.

In some implementations, a third word line 360c is coupled to a second row 301b of memory cells of the second block 354, and a fourth word line 360d is coupled to a first row 301a of memory cells of a third block 356. In some implementations, the third word line 360c and the fourth word line 360d are connected through a second conductive structure 368b to form a second continuous conductive line 370b. In some implementations, the first continuous conductive line 370a and the second continuous conductive line 370b are adjacent to each other along both the word line direction and the bit line direction.

The conductive structure 368 connecting two word lines 360 are located in a corresponding isolating region 314. An area of the corresponding conductive structure 368 is within an area of a corresponding isolating region 314 between adjacent blocks. For example, the first conductive structure 368a can be in the first isolating region 314a between the first block 352 and the second block 354. The first conductive structure 368a has a smaller area than that of the first isolating region 314a such that the first conductive structure 368a is separate from semiconductor bodies 130 of transistors 126 in neighboring blocks. Likewise, in some implementations, an area of the second conductive structure 368b is within an area of a second corresponding isolating region 314b between the second block 354 and the third block 356.

Multiple insulating regions 358 can be formed to separate adjacent word lines 360. For example, the second insulating region 358b separates the first word line 360a from the third word line 360c. As described above, the insulating region can be formed with a dielectric material, including but not limited to, silicon oxide, silicon nitride, silicon oxynitride, or any combination thereof.

In some implementations, the conductive structure 368 is separate from the insulating regions 358. For example, the first conductive structure 368a can be separate from any insulating region 358.

In some implementations, the semiconductor device 350 includes multiple separation regions 378. A separation region 378 is between adjacent rows of memory cells in a same block and configured to separate such adjacent rows. The separation region 378 can be also referred as TISO 378 in this disclosure. For example, the first separation region 378a (TISO) is located between the second row 301b of memory cells and the third row 301c of memory cells in the first block 352. The third row 301c of the memory cells are sequential to the second row 301b of memory cells along Y direction or the bit line direction.

In some implementations, an insulating region 358 is formed on an end of a separation region 378. The insulating region 358 is also at an end of at least one adjacent word lines 360. The word lines 360 are adjacent to the separation region 378. For example, the first insulating region 358a is at the left end of both first word line 360a and the fifth word line 360e. the first insulating region 358a is also at the left end of the first separation region 378a. The first separation region 378a is between the first word line 360a and the fifth word line 360e along bit line direction in the first block 352. In other words, the first word line 360a, the first separation region 378a and the fifth word line 360e are arranged consecutively along the bit line direction, e.g., Y direction. The first insulating region 358a is formed with a lateral dimension along Y direction large enough to intersect or cut all these structures, e.g., the first word line 360a, the first separation region 378a and the fifth word line 360e.

A conductive structure 368 can be within the insulating region 358 and coupled to the separation region 378. For example, the first insulating region 358a is on an end of the first separation region 378a. The third conductive structure 368c is located within the first insulating region 358a and coupled to the first separation region 378a. In some implementations, conductive structures 368 partially extend into the corresponding insulating regions 358 along Z direction such that the conductive structures 368 can be in contact with the shielding conductive structure 170 in a separation region 378 (TISO).

In some implementations, the first separation region 378a has a first end 372a and a second end 372b. The second end 372b is opposite to the first end 372a along X direction or the word line direction. In some implementations, a corresponding second separation region 378b of the second block 354 has a third end 374a and a fourth end 374b. The fourth end 374b is opposite to the third end 374a along the word line direction. The second separation region 378b is adjacent to the first separation region 378a along word line direction. In some implementations, the second end 372b of the first separation region 378a and the third end 374a of the corresponding second separation region 378b are at two ends of the corresponding isolating region, e.g., the first isolating region 314a, between the first block 352 and the second block 354. In some implementations, the third conductive structure 368c is on the first end 372a of the first separation region 378a, and a second conductive structure 368b is on the third end 374a of the corresponding second separation region 378b.

In some implementations, two conductive structures 368 coupled to two adjacent separation regions 378 in a same block are on opposite ends of the two adjacent separation regions 378. The two adjacent separation regions 378 of a same block are adjacent to or consecutive to each other along the third direction, e.g., bit line direction. For example, as illustrated in FIG. 3B, the third conductive structure 368c and the fourth conductive structure 368d are coupled to the two adjacent separation regions 378 (TISOs) in the first block 352. More specifically, the third conductive structure 368c is coupled to the left end of the first separation region 378a, while the fourth conductive structure 368d is coupled to the right end of third separation region 378c. The first separation region 378a and the third separation region 378c are consecutive to each other along the bit line direction. The left ends are opposite to the right ends along X direction or the word line direction.

FIGS. 4A-4C illustrate views of the semiconductor device 300 at various stages of a manufacturing process. More specifically, diagram (a) of FIG. 4A illustrates a top view of X-Y plane, while diagram (b) of FIG. 4A is a cross-sectional view in Y-Z plane (e.g., in the A-A plane). The X direction can be the word line (WL) direction. The Y direction can be the bit line (BL) direction.

In some implementations, as illustrated in diagram (a) of FIG. 4A, an array of body trenches 426 is formed on a front side 409 of a substrate 402. Each body trench 426 extends along the Y direction (BL direction) and two adjacent body trenches 426 are distributed along the X direction (WL direction). A width of a body trench 426 in the X direction is shorter than a length of the body trench 426 in the Y direction. As illustrated in diagram (b) of FIG. 4A, the body trenches 426 are etched vertically along Z direction. Each body trench 426 can have a substantially similar or same pitch, critical dimension (CD), or size, etc. Isolating regions 314 between two adjacent memory blocks can be formed together with the body trenches 426. The isolating region 314 can have a greater lateral dimension compared to that of the individual body trench 426 along the bit line direction. For example, each of the first separation region 314a and the second separation region 314b can be wider than individual body trench 426 along the Y direction (bit line direction). In some implementations, the etching of substrate 402 to form body trenches 426 and isolating regions 314 involves one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

An annealing process can be subsequently performed to form a thin layer of silicon oxide along vertical sidewalls 428 of the body trenches 426 or isolating regions 314 to repair the exposed silicon surface. A dielectric filling material 440 can be then deposited to fill in the body trenches 426 and the isolating regions 314 followed by a polishing process to have a top surface of a dielectric filling material 440 flush with a top surface of hard mark 422. The dielectric filling material 440 can have a dielectric material including, but not limited to, silicon oxide, silicon nitride, silicon oxynitride, low-k dielectrics, or any combination thereof. The dielectric filling material 440 can be deposited by one or more thin film deposition processes including, but not limited to, CVD, PVD, ALD, sputtering, or any combination thereof. The polishing process can include, but not limited to, chemical mechanical polishing (CMP), mechanical polishing, electrochemical polishing, ultrasonic polishing, or any combination thereof.

As illustrated in FIG. 4B, vertical gate (VG) trenches 442 are formed with each VG trench 442 extending along WL line direction (X direction). The vertical gate trenches 442 are extending through substrate 402 and dielectric fillings 440 along Z direction. In some implementations, the critical dimension (CD), such as the width and depth, and pitches between adjacent VG trenches 442 are substantially similar. In some implementations, the VG trenches 442 have different lengths along WL direction, as shown. The long VG trenches 442a can extend through multiple blocks along the WL direction. In contrast, the short VG trenches 442b can extend within one corresponding block. The long VG trenches 442a and the short VG trenches 442b can be alternative with each other along Y direction, e.g., the bit line direction. The trench etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof. In some implementations, a self-aligned double patterning (SADP) is employed to create finer and more densely packed trenches features with smaller pitches.

FIG. 4C illustrates a top view of the semiconductor device 300, which is the same as FIG. 3A. From FIG. 4B to FIG. 4C, multiple process sub-steps can be involved to form vertical transistors 126, word lines 310, conductive structures 328, separation regions 338 (TISO), and insulating regions 322 (gate cuts). Although not illustrated in FIG. 4C, the process sub-steps are described below.

An annealing process can be performed to form a thin layer of silicon oxide along vertical sidewalls of VG trenches 442 to repair the exposed silicon surface. In addition, or alternatively, a liner layer, e.g., silicon oxide, can be deposited on sidewalls of VG trenches 442. A sacrificial material, e.g., silicon oxycarbide (SiOC), can also be formed in the VG trenches 442. The sacrificial material in the short VG trenches 442b can be subsequently removed, while the sacrificial material in the long VG trenches 442a can be retained. Long VG trenches 442a can be then expanded along BL direction (Y axis) so that the width of long VG trenches 442a along Y-axis is wider than that of short VG trenches 442b. In some implementations, the long VG trenches 442a are also deeper than the short VG trenches 442b along Z direction. In some implementations, the expanding of long VG trenches 442a is achieved by etching, involving one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

A gate dielectric 132 can be deposited on sidewalls of VG trenches 442 to form gate oxide. The gate dielectric 132 can include a dielectric material, such as silicon oxide, silicon nitride, or high-k dielectrics including, but not limited to, Al2O3, HfO2, Ta2O5, ZrO2, TiO2, any material with a dielectric constant higher than or equal to 3.9, or any combination thereof. A gate 134 or the word line 310 can be subsequently deposited which abut the gate dielectric 132. In some implementations, gate 134 or the word line 310 includes a conductive material including, but not limited to W, Co, Cu, Al, TiN, TaN, polysilicon, silicide, or any combination thereof. In some implementations, the gate 134 or the word line 310 includes multiple conductive layers, such as a W layer over a TiN layer.

A gate dielectric 132 and a gate 134 form a gate structure 136. In one example, the gate structure 136 may be a “gate oxide/gate poly” gate in which the gate dielectric 132 includes silicon oxide and gate electrode 134 includes doped polysilicon. In another example, gate structure 136 may be a high-K metal gate (HKMG) in which gate dielectric 132 includes a high-k dielectric and gate electrode 134 includes a metal.

A shielding conductive material can be deposited into short VG trenches 442b to form separation regions 338. The shielding conductive material can form the shielding conductive structures 170 in FIG. 1. The shielding conductive material can include, without limitation to, W, Co, Cu, Al, TiN, TaN, polysilicon, silicide, or any combination thereof. In some implementations, the separation regions 338 include dielectric material in the top portions and/or bottom portions of short VG trenches 442b, while the shielding conductive material is in the middle portion of the short VG trenches 442b.

Multiple insulating regions 322 are formed. The insulating region 322 can be formed by first etching trenches and subsequently filling the trenches with a dielectric material. The dielectric material can include, but not limited to, silicon oxide, silicon nitride, silicon oxynitride, or any combination thereof. As described above, the insulating regions 322 can isolate adjacent word lines 310. An insulating region 322 can also cut two adjacent word lines 310 in the same block. For example, the first insulating region 322a cuts or intersects a portion of the third word line 310c and a portion of the fourth word line 310d. In some implementations, the insulating regions 322 are located on opposite ends of the adjacent separation regions 338 in the same block, as illustrated in 4C.

Conductive structures 328 are formed. In some implementations, at least one conductive structure 328 is formed in the insolating regions 314 between two adjacent memory blocks. The conductive structure 328 couples one or more corresponding word lines 310, enabling connections between memory cells in adjacent memory blocks. The conductive structure 328 can couple to a word line driver 202. Therefore, the conductive structure 328 effectively couples the corresponding memory cell to the word line driver 202. This coupling allows the word line driver 202 to apply voltage signals or pulses to the word lines 310, which in turn affects the operation of the memory cell. The conductive structure 328 can be made of materials, including without limiting to, W, Co, Cu, Al, TiN, TaN, polysilicon, or any combination thereof. In some implementations, the conductive structure 328 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, at least one conductive structure 328 is formed in the insulating regions 322. In some implementations, conductive structures 328 partially extend into the corresponding insulating regions 322 along Z direction such that the conductive structures 328 can be in contact with and thus electrically connected to the shielding conductive structure 170 in a TISO 338. As described above, the shielding conductive material, e.g., the shielding conductive structure 170 in FIG. 1, can be coupled to a low voltage (e.g., ground or a fixed negative voltage) through the corresponding conductive structures, which can reduce charge build-up in the memory cells, thereby mitigating the floating body effect in the memory cells. The conductive structures 328 can have a smaller lateral dimension than that of the insulating regions 322, as shown in FIG. 4C.

It is understood that the conductive structures 328 for word lines 310 and the separation regions 338 can have substantially similar structures, dimension and/or materials, and can be formed concurrently in the same steps. It is further understood that the conductive structures 328 for word lines 310 and the separation regions 338 can extend along Z direction beyond the word lines 310 or the separation regions 338. This allows the far ends of the conductive structures 328 to be connected to metal lines or circuitries in different planes in the vertical direction (e.g., Z direction) or different semiconductor structures (e.g., the first semiconductor structure 102).

In some implementations, the insulating regions 322 are formed from the front side 409 of the substrate 402 (e.g., as illustrated in FIG. 4A), while the conductive structures 328 are formed from the back side 411 of the substrate 402 (e.g., as illustrated in FIG. 4A). This approach can widen the process window. Different processes can have different requirements or constraints. By dividing the manufacturing steps between the front and back sides of the substrate, manufacturers can tailor each process independently, potentially improving process control and yield. In addition, forming structures on both sides of the substrate can help thermal management. Heat dissipation can be more effectively managed, reducing the risk of overheating and improving overall reliability.

In some implementations, both the insulating regions 322 and the conductive structures 328 are formed from the front side 409 of the substrate 402. Forming both structures on the same side of the substrate eases the process complexity. For example, when structures are formed on the same side of the substrate, alignment errors between different layers are reduced. Furthermore, having both structures on one side of the substrate simplifies the process flow by eliminating the need for flipping the substrate and deploying a bonding wafer during manufacturing.

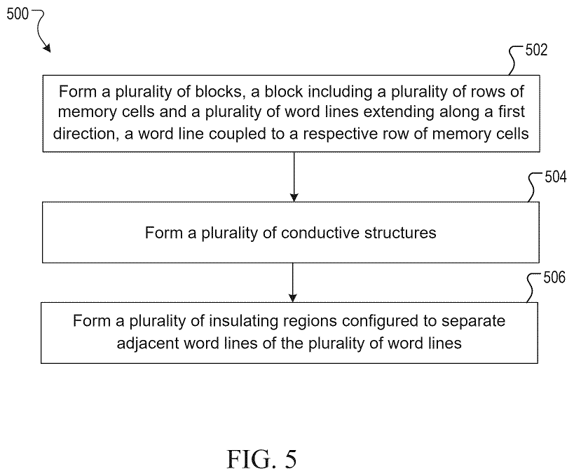

FIG. 5 illustrates a flow chart of an example process 500 to form a semiconductor device. The semiconductor device can be, e.g., the semiconductor device 100 of FIG. 1, the semiconductor device 300 of FIGS. 3A and 4A-4C, or the semiconductor device 350 of FIG. 3B.

At step 502, multiple blocks are formed. Two adjacent blocks are separated by a corresponding isolating region. A block includes multiple rows of memory cells and multiple word lines extending along a first direction. A memory cell includes a transistor having a gate extending along a second direction perpendicular to the first direction. A word line is coupled to gates of transistors of a corresponding row of memory cells. The blocks can be, e.g., the first block 302 of FIGS. 3A and 4A-4C, the second block 304 of FIGS. 3A and 4A-4C, the third block 306 of FIGS. 3A and 4A-4C, the first block 352 of FIG. 3B, the second block 354 of FIG. 3B, or the third block 356 of FIG. 3B. Multiple rows of memory cells can be, e.g., the first row 301a of memory cells of FIGS. 3A-3B and 4C, the second row 301b of memory cells of FIGS. 3A-3B and 4C, or the third row 301c of memory cells of FIGS. 3A-3B and 4C. The word lines can be, e.g., the word lines 310 of FIGS. 3A and 4C, or the word lines 360 of FIG. 3B. The transistors can be, e.g., the transistors 126 of FIGS. 1, 3A-3B and 4C. The gate can be, e.g., the gate electrode 134 of FIGS. 1, 3A-3B and 4C. The first direction can be, e.g., the X direction or word line direction of FIGS. 3A-4C. The second direction can be, e.g., the Z direction of FIGS. 1 and 3A-4C. The third direction can be, e.g., the Y direction or bit line direction of FIGS. 1 and 3A-4C.

At step 504, multiple conductive structures are formed. A first word line in a first block and a second word line in a second block are connected to a corresponding conductive structure. The first block is adjacent to the second block along the first direction. An area of the corresponding conductive structure is within an area of a corresponding isolating region between the first block and the second block. The conductive structures can be, e.g., the conductive structure 328 of FIGS. 3A and 4C, or the conductive structure 368 of FIG. 3B. The isolating region can be, e.g., the isolating region 314 of FIGS. 3A-4C.

At step 506, multiple insulating regions are formed, which are configured to separate adjacent word lines. The insulating regions can be, e.g., the insulating region 322 of FIGS. 3A and 4C, or the insulating region 358 of FIG. 3B.

In some implementations, a conductive structure is separate from the plurality of insulating regions. For example, as illustrated in FIG. 3A, the first conductive structure 328a is separate from any insulating region 322.

In some implementations, the first word line is coupled to a first row of memory cells of the first block, and the second word line is coupled to a first row of memory cells of the second block. The first row of memory cells of the first block and the first row of memory cells of the second block are spaced from each other by corresponding isolating region along the first direction.

In some implementations, the first block includes a first row of memory cells and a second row of memory cells that are sequential along the third direction, e.g., bit line direction. The second block includes a first row of memory cells and a second row of memory cells that are sequential along the third direction, e.g., the bit line direction. The first word line is coupled to the second row of memory cells of the first block. The second word line is coupled to the first row of memory cells of the second block. The second row of memory cells of the first block and the first row of memory cells of the second block being spaced from each other. The first word line can be, e.g., the first word line 360a of FIG. 3B. The second word line can be, e.g., the second word line 360b of FIG. 3B.

In some implementations, as illustrated in FIGS. 3A-3B and 4C, the method includes forming multiple separation regions extending along the first direction, e.g., the word line direction. A separation region is configured to separate adjacent rows of memory cells in a same block. An insulating region is formed on an end of the separation region. A corresponding conductive structure is formed within the insulating region and coupled to the separation region. The separation region can be, e.g., the separation regions 338 of FIGS. 3A and 4C, or the separation regions 378 of FIG. 3B.

In some implementations, the insulating region cuts an end of at least one adjacent word line. The at least one adjacent word line is adjacent to the separation region along a third direction, e.g., bit line direction.

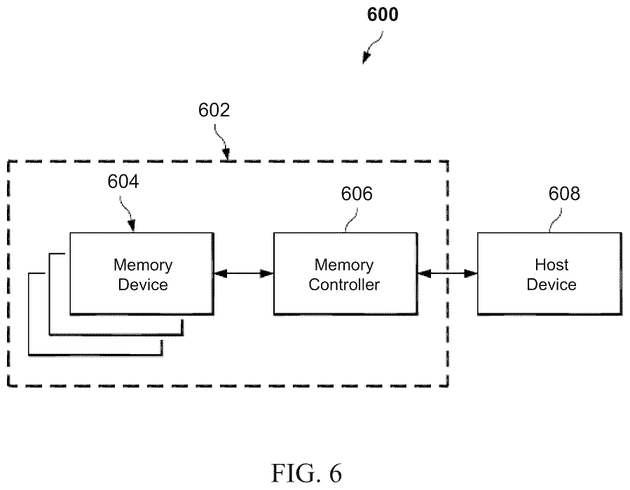

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the 3D semiconductor device 100 of FIG. 1, or a part of the 3D semiconductor device 100 (e.g., the second semiconductor structure 104 of FIG. 1), or the semiconductor device 300 of FIG. 3A, or a structure at an intermediate fabrication process of the 3D semiconductor device 300 of FIGS. 4A-4C, or the 3D semiconductor structure 350 of FIG. 3B.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include multiple conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate multiple channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagate signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagate signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device comprising:
a plurality of blocks, each block comprising a plurality of rows of memory cells, each row of memory cells extending along a first direction, a memory cell of the plurality of rows of memory cells comprising a transistor having a gate extending along a second direction perpendicular to the first direction;
a plurality of word lines, a word line of the plurality of word lines being coupled to gates of transistors of two adjacent rows of memory cells of two adjacent blocks that are spaced by a corresponding isolating region, the word line extending along the first direction;
a plurality of conductive structures; and
a plurality of insulating regions configured to separate adjacent word lines of the plurality of word lines,
wherein the word line is connected to a corresponding conductive structure of the plurality of conductive structures, and an area of the corresponding conductive structure is within an area of the corresponding isolating region between the two adjacent rows of memory cells of the two adjacent blocks.

2. The semiconductor device of claim 1, wherein the area of the corresponding conductive structure overlaps a portion of the word line.

3. The semiconductor device of claim 1, wherein the word line is a first word line, the two adjacent rows of memory cells of the two adjacent blocks are a first row of memory cells of a first block and a first row of memory cells of a second block,
wherein a second word line of the plurality of word lines is coupled to a second row of memory cells of the second block and a second row of memory cells of a third block adjacent to the second block, and
wherein the first word line and the second word line are adjacent to each other at least along a third direction perpendicular to the first direction and the second direction.

4. The semiconductor device of claim 3, wherein the corresponding conductive structure is a first conductive structure, and wherein the plurality of conductive structures comprises a second conductive structure coupled to the second word line, and an area of the second conductive structure is within an area of a second corresponding isolating region between the second block and the third block.

5. The semiconductor device of claim 1, further comprising a plurality of separation regions, a separation region of the plurality of separation regions being between adjacent rows of memory cells in a same block of the plurality of blocks,
wherein an insulating region of the plurality of insulating regions is on an end of the separation region, and
wherein a second corresponding conductive structure of the plurality of conductive structures is within the insulating region and coupled to the separation region.

6. The semiconductor device of claim 5, wherein the insulating region is at an end of at least one adjacent word line of the plurality of word lines, the at least one adjacent word line being adjacent to the separation region along a third direction perpendicular to the first direction and the second direction.

7. The semiconductor device of claim 6, wherein two adjacent conductive structures of the plurality of conductive structures are coupled to two adjacent separation regions of the plurality of separation regions of two adjacent blocks of the plurality of blocks, the two adjacent separation regions being adjacent to each other along the first direction, and wherein the adjacent conductive structures are on two ends of a corresponding isolating region between the two adjacent separation regions of the two adjacent blocks, the two ends of the corresponding isolating region being opposite to each other along the first direction.

8. The semiconductor device of claim 6, wherein two conductive structures of the plurality of conductive structures coupled to two adjacent separation regions of a same block are on opposite ends of the two adjacent separation regions, the two adjacent separation regions of the same block being adjacent to each other along the third direction, the opposite ends being opposite to each other along the first direction.

9. A semiconductor device comprising:
a plurality of blocks, two adjacent blocks of the plurality of blocks being separated by a corresponding isolating region, a block of the plurality of blocks comprising:
a plurality of rows of memory cells, each row of memory cells extending along a first direction, a memory cell of the plurality of rows of memory cells comprising a transistor having a gate extending along a second direction perpendicular to the first direction, and
a plurality of word lines extending along the first direction, a word line of the plurality of word lines being coupled to gates of transistors of a corresponding row of memory cells of the block of the plurality of blocks;
a plurality of conductive structures; and
a plurality of insulating regions configured to separate adjacent word lines of the plurality of word lines,
wherein the plurality of blocks comprises a first block and a second block, wherein a first row of memory cells and a second row of memory cells of the first block are sequential along a third direction perpendicular to the first direction and the second direction, and a first row of memory cells of the second block is adjacent to the first row of memory cells of the first block along the first direction,
wherein a first word line of the plurality of word lines is coupled to the second row of memory cells of the first block, and a second word line of the plurality of word lines is coupled to the first row of memory cells of the second block,
wherein the first word line and the second word line are connected through a corresponding conductive structure of the plurality of conductive structures, and
wherein an area of the corresponding conductive structure is within an area of a corresponding isolating region between the first block and the second block.

10. The semiconductor device of claim 9, wherein the connected first word line and second word line has a zig-zag shape.

11. The semiconductor device of claim 9, wherein the corresponding conductive structure is separate from the plurality of insulating regions.

12. The semiconductor device of claim 9, wherein the first word line and the second word line are connected to form a first continuous conductive line,
wherein a third word line of the plurality of word lines is coupled to a second row of memory cells of the second block, and a fourth word line is coupled to a first row of memory cells of a third block adjacent to the second block along the first direction,
wherein the corresponding conductive structure is a first conductive structure, and the plurality of conductive structures comprises a second conductive structure,
wherein the third word line and the fourth word line are connected through the second conductive structure of the plurality of conductive structures to form a second continuous conductive line, and
wherein the first continuous conductive line and the second continuous conductive line are adjacent to each other along the first direction and a third direction perpendicular to the first direction and the second direction.

13. The semiconductor device of claim 9, further comprising a plurality of separation regions, a separation region of the plurality of separation regions being configured to separate adjacent rows of memory cells in a same block of the plurality of blocks,
wherein an insulating region of the plurality of insulating regions is on an end of the separation region, and
wherein a second corresponding conductive structure of the plurality of conductive structures is within the insulating region and coupled to the separation region.

14. The semiconductor device of claim 13, wherein the insulating region is at an end of at least one adjacent word line of the plurality of word lines, the at least one adjacent word line being adjacent to the separation region along a third direction perpendicular to the first direction and the second direction.

15. The semiconductor device of claim 14, wherein the separation region is a first separation region of the first block, the corresponding conductive structure is a first conductive structure, and the first separation region has a first end and a second end opposite to the first end along the first direction,
wherein a corresponding second separation region of the second block has a third end and a fourth end opposite to the third end along the first direction, the corresponding second separation region being adjacent to the first separation region along the first direction,
wherein the second end of the first separation region and the third end of the corresponding second separation region are at two ends of the corresponding isolating region between the first block and the second block, and
wherein the first conductive structure is on the first end of the first separation region, and a second conductive structure of the plurality of conductive structures coupled to the corresponding second separation region is on the third end of the corresponding second separation region.

16. The semiconductor device of claim 14, wherein two conductive structures of the plurality of conductive structures coupled to two adjacent separation regions of the plurality of separation regions of a same block are on opposite ends of the two adjacent separation regions, the two adjacent separation regions of a same block being adjacent to each other along the third direction, the opposite ends being opposite to each other along the first direction.

17. A method, comprising:
forming a plurality of blocks, two adjacent blocks of the plurality of blocks being separated by a corresponding isolating region, a block of the plurality of blocks comprising:
a plurality of rows of memory cells, each row of memory cells extending along a first direction, a memory cell of the plurality of rows of memory cells comprising a transistor having a gate extending along a second direction perpendicular to the first direction, and
a plurality of word lines extending along the first direction, a word line of the plurality of word lines coupled to gates of transistors of a corresponding row of memory cells of a block of the plurality of blocks;
forming a plurality of conductive structures; and
forming a plurality of insulating regions configured to separate adjacent word lines of the plurality of word lines,
wherein a first word line of the plurality of word lines in a first block of the plurality of blocks and a second word line of the plurality of word lines in a second block of the plurality of blocks are connected to a corresponding conductive structure of the plurality of conductive structures, the first block being adjacent to the second block along the first direction, and
wherein an area of the corresponding conductive structure is within an area of a corresponding isolating region between the first block and the second block.

18. The method of claim 17, wherein the first word line is coupled to a first row of memory cells of the first block, the second word line is coupled to a first row of memory cells of the second block, the first row of memory cells of the first block and the first row of memory cells of the second block being spaced from each other along the first direction.

19. The method of claim 17, wherein the first block comprises a first row of memory cells and a second row of memory cells that are sequential along a third direction perpendicular to the first direction and the second direction, and the second block comprises a first row of memory cells and a second row of memory cells that are sequential along the third direction, and
wherein the first word line is coupled to the second row of memory cells of the first block, the second word line is coupled to the first row of memory cells of the second block, the second row of memory cells of the first block and the first row of memory cells of the second block being spaced from each other along the first direction and the third direction.

20. The method of claim 17, further comprising:
forming a plurality of separation regions extending along the first direction, a separation region of the plurality of separation region configured to separate adjacent rows of memory cells in a same block of the plurality of blocks,
wherein an insulating region of the plurality of insulating regions is formed on an end of the separation region, and
wherein a second corresponding conductive structure of the plurality of conductive structures is formed within the insulating region and coupled to the separation region.
